(19) United States
(12) Patent Application Publication
(10) Pub. No.: US 2025/0148179 A1
(43) Pub. Date: May 8, 2025

(54) AREA OPTIMIZED MEMORY IMPLEMENTATION USING DEDICATED MEMORY PRIMITIVES

(71) Applicant: Xilinx, Inc., San Jose, CA (US)

(72) Inventors: Pradip Kar, San Jose, CA (US); Chaithanya Dudha, San Jose, CA (US); Nithin Kumar Guggilla, Hyderabad (IN)

(73) Assignee: Xilinx, Inc., San Jose, CA (US)

(21) Appl. No.: 18/503,047

(22) Filed: Nov. 6, 2023

(51) Int. Cl. G06F 30/327; G06F 30/323

(52) U.S. Cl. CPC G06F 30/327; G06F 30/323

(57) ABSTRACT

A memory includes a read circuit having a first primitive configured to output a first data item based on least significant bits (LSBs) of a read address and a multiplexer coupled to the primitive. The multiplexer outputs a selected bit from the first data item as read data based on most significant bits (MSBs) of the read address. The memory includes a write circuit having a second primitive that outputs a second data item based on LSBs of a write address and a modifier circuit that generates a third data item by modifying a bit of the second data item to correspond to write data. The bit is at a location within the second data item selected based on MSBs of the write address. The modifier circuit writes the third data item to a location in the write primitive based on the LSBs of the write address.

### RESERVATION OF RIGHTS IN COPYRIGHTED MATERIAL

A portion of the disclosure of this patent document contains material which is subject to copyright protection. The copyright owner has no objection to the facsimile reproduction by anyone of the patent document or the patent disclosure, as it appears in the Patent and Trademark Office patent file or records, but otherwise reserves all copyright rights whatsoever.

### TECHNICAL FIELD

This disclosure relates to integrated circuits (ICs) and, more particularly, to implementing a memory within an IC using dedicated memory primitives of the IC.

### BACKGROUND

Some integrated circuits (ICs) are manufactured to include predefined circuit blocks referred to as primitives that may be used to implement a user's circuit design. As an example, a programmable IC such as a field programmable gate array (FPGA) may include a variety of different types of memory primitives. The memory primitives are dedicated circuit structures available on the IC. Each memory primitive may include a random-access memory (RAM) circuit and ports that support read operations and/or write operations to the RAM circuit. The ports may be connected to other circuits and/or systems in the IC to implement the user's circuit design.

In some cases, the memory primitive may be programmable or configurable. The memory primitives may be configured to operate with different widths resulting in different logical organizations of the RAM circuit in terms of number of data items that may be stored (e.g., depth) and width of the data items. The memory primitives have a maximum width and a minimum width. As an example, a memory primitive may include a RAM circuit capable of storing 36 kbits of data. For purposes of illustration, the memory primitive may be configurable to operate as a memory capable of storing 4 k words (e.g., depth) each being 9 bits (e.g., width), 2 k words each being 18 bits, or 1 k words each being 36 bits. In each case, the depth and width memory primitive varies.

In cases where the user's circuit design requires a memory that is deep and narrower than a minimum width available for the memory primitive, the Electronic Design Automation (EDA) tools often implement a physical memory from the circuit design in a non-optimal way. That is, the EDA tools often link multiple memory primitives through external circuitry or internal cascading. This approach can degrade timing performance of the circuit design since data read out from the memory primitives must be conveyed through either a cascade chain or the external circuitry (e.g., multiplexers). Further, any memories formed using previous integrated circuit technologies or architectures may not be retargeted to newer IC architectures with different memory primitives.

For example, consider a circuit design that specifies a memory having a capacity of 32K entries each being 1-bit in width. In this example, the maximum address a single memory primitive can decode is 4K. Accordingly, eight different memory primitives would be needed to implement the 32 k by 1-bit memory in a target IC. Because each entry of each memory primitive will have only 1-bit of data stored therein, the remaining bits of each entry remain empty meaning that each memory primitive is severely underutilized.

### SUMMARY

In one or more example implementations, a memory includes a read circuit. The read circuit includes a first memory primitive configured to output a first data item based on least significant bits of a read address. The read circuit includes a multiplexer coupled to the first memory primitive. The multiplexer is configured to output a selected bit from the first data item as read data based on most significant bits of the read address. The memory includes a write circuit coupled to the read circuit. The write circuit includes a second memory primitive configured to output a second data item based on least significant bits of a write address. The write circuit includes a modifier circuit configured to generate a third data item by modifying a bit of the second data item to correspond to write data, wherein the bit is at a location within the second data item selected based on most significant bits of the write address. The modifier circuit is configured to write the third data item to a location in the second memory primitive based on the least significant bits of the write address.

In one or more example implementations, a method includes selecting a hardware description language (HDL) memory from a circuit design. The method includes generating a read circuit. The read circuit is configured to select a first data item from a first memory primitive based on least significant bits of a read address and output a selected bit from the first data item as read data based on most significant bits of the read address. The method includes generating a write circuit. The write circuit is configured to select a second data item from a second memory primitive based on least significant bits of a write address and generate a third data item by modifying a bit of the second data item to correspond to write data. The bit is at a location within the second data item selected based on most significant bits of the write address. The write circuit is configured to write the third data item to a location in the second memory primitive based on the least significant bits of the write address.

In one or more example implementations, a method includes, in response to receiving a write address, outputting a first data item from a second memory primitive based on least significant bits of the write address. The method includes generating a second data item from the first data item by modifying a bit of the first data item to correspond to write data. The bit is at a location within the first data item selected based on most significant bits of the write address. The method includes storing the second data item to a location in the second memory primitive based on the least significant bits of the write address.

This Summary section is provided merely to introduce certain concepts and not to identify any key or essential features of the claimed subject matter. Other features of the inventive arrangements will be apparent from the accompanying drawings and from the following detailed description.

### BRIEF DESCRIPTION OF THE DRAWINGS

The inventive arrangements are illustrated by way of example in the accompanying drawings. The drawings, however, should not be construed to be limiting of the inventive arrangements to only the particular implementations shown. Various aspects and advantages will become apparent upon review of the following detailed description and upon reference to the drawings.

FIG. 1 illustrates an example of a system for implementing a circuit design.

FIG. 2 is a visualization of a hardware description language (HDL) memory and an example memory primitive available within a target integrated circuit (IC).

FIGS. 3A and 3B illustrate cascaded and multiplexed circuit architectures, respectively.

FIG. 4 illustrates an example of a read circuit generated by the system of FIG. 1.

FIG. 5 illustrates an example of a write circuit generated by the system of FIG. 1.

FIG. 6 illustrates a memory formed of a read circuit and a write circuit.

FIG. 7 illustrates an example of a modifier circuit.

FIG. 8 illustrates an example of a latency compensation circuit.

FIG. 9 illustrates another example of a latency compensation circuit.

FIG. 10 is an example method of implementing a memory as described within this disclosure.

FIG. 11 is another example method of implementing a memory as described within this disclosure.

FIG. 12 is an example method of operation of a memory circuit generated as described within this disclosure.

FIG. 13 illustrates an example implementation of a data processing system.

### DETAILED DESCRIPTION

While the disclosure concludes with claims defining novel features, it is believed that the various features described within this disclosure will be better understood from a consideration of the description in conjunction with the drawings. The process(es), machine(s), manufacture(s) and any variations thereof described herein are provided for purposes of illustration. Specific structural and functional details described within this disclosure are not to be interpreted as limiting, but merely as a basis for the claims and as a representative basis for teaching one skilled in the art to variously employ the features described in virtually any appropriately detailed structure. Further, the terms and phrases used within this disclosure are not intended to be limiting, but rather to provide an understandable description of the features described.

This disclosure relates to integrated circuits (ICs) and, more particularly, to implementing a memory within an IC using dedicated memory primitives of the IC. A memory primitive refers to a dedicated or predetermined memory circuit block that is available on a particular IC in which a circuit design is to be physically realized (e.g., the “target IC”). Typically, the memory primitive is the smallest circuit block of that type (e.g., a memory in this case) that is available in the target IC.

Electronic Design Automation (EDA) tools process a circuit design through a design flow that typically includes synthesis, placement, and routing. During synthesis, for example, the EDA tools may detect memories specified in the circuit design (e.g., in the register-transfer level or “RTL” description) that must be physically realized in the target IC using one or more of the available memory primitives. In cases where the width of the memory specified in the circuit design is less than the minimum width of the memory primitive to be used to build that memory, the EDA tools often implement the memory in the target IC with a sub-optimal circuit architecture. The resulting memory, as physically realized in the target IC, for example, utilizes a greater number of memory primitives than is necessary thereby leaving much of the storage of the memory unused during operation of the IC.

In accordance with the inventive arrangements described within this disclosure, systems, methods, and computer program products are disclosed that are capable of implementing memories, e.g., RAMs, in an IC using fewer memory primitives than is the case with other conventional circuit design implementation tools and/or techniques. The inventive arrangements are capable of implementing memory circuits for memories specified in circuit designs (e.g., HDL memories) where the HDL memories have widths that are narrower than the minimum width of the memory primitive used to build the memory circuit. Further, the memory circuit is constructed using a reduced number of such memory primitives. By reducing the number of memory primitives needed to implement an HDL memory, an IC may be used to physically realized a larger circuit design than would otherwise be the case and/or implement a circuit design more efficiently using fewer circuit resources.

Further aspects of the inventive arrangements are described below with reference to the figures. For purposes of simplicity and clarity of illustration, elements shown in the figures have not necessarily been drawn to scale. For example, the dimensions of some of the elements may be exaggerated relative to other elements for clarity. Further, where considered appropriate, reference numbers are repeated among the figures to indicate corresponding, analogous, or like features.

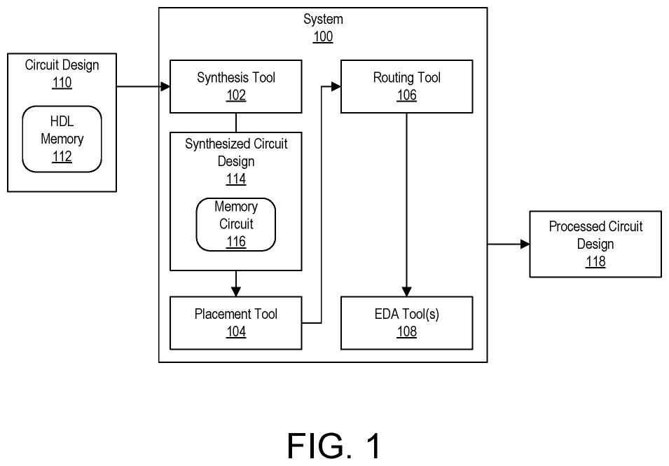

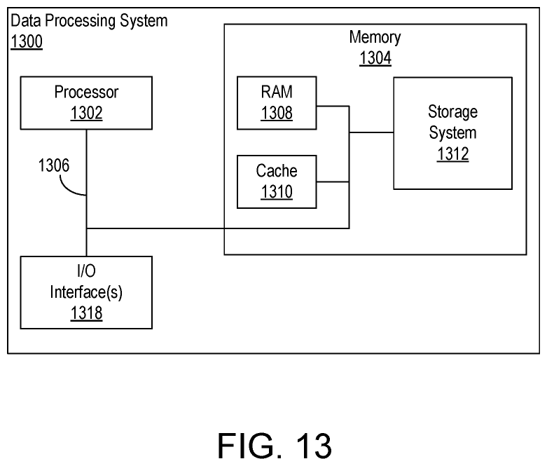

FIG. 1 illustrates an example of a system 100 for implementing a circuit design. System 100 illustratively includes a synthesis tool 102, a placement tool 104, a routing tool 106, and one or more other optional EDA tool(s) 108. In one aspect, synthesis tool 102, placement tool 104, routing tool 106, and EDA tool(s) 108 are operatively coupled or communicatively linked so as to operate in coordination with one other to implement a design flow through which a circuit design 110 may be processed. In an example implementation, system 100 is implemented as a set of computer system instructions (software or program code) that execute on one or more processors such as processor(s) 1302 of data processing system 1300 described with reference to FIG. 13. In other examples, system 100 can be implemented as dedicated circuitry or as a combination of circuitry and software.

System 100 is capable of receiving circuit design 110 as input. Circuit design 110 may be specified using a hardware description language (HDL), e.g., as a register transfer level (RTL) description. Examples of HDLs include, but are not limited to, VHDL and Verilog. In the example of FIG. 1, circuit design 110 includes an HDL memory 112. HDL memory 112 is a memory specified in RTL, e.g., as a data structure, as part of circuit design 110. HDL memory 112 may specify a random-access memory (RAM). HDL memory 112 is not yet implemented or specified in the form of memory primitives and/or additional circuit blocks that are available in the target IC. For example, HDL memory 112 is not yet synthesized into a netlist.

Example 1 below illustrates an example of HDL memory 112 as may be included within circuit design 110. The HDL listed in Example 1 specifies a 32 kbit×1 bit RAM. It should be appreciated that HDL memories of other depths and/or widths may be specified and that the HDL included in Example 1 is for purposes of illustration and not limitation.

### Example 1

```
// 32kbit x 1bit RTL RAM
(*ram_style = “block” *) reg [0:0] mem [32767:0]
always @(posedge clk) begin
  if (ena) begin
    if (wen)
      mem [waddr] <= din;
    dout <= mem [raddr]
  end
end
```

Synthesis tool 102 is capable of synthesizing circuit design 110 to convert circuit design 110 from an HDL description to a netlist, e.g., a gate level implementation, and map the netlist to primitives available on the target IC. In the example of FIG. 1, the synthesized and mapped version of circuit design 110 is illustrated as synthesized circuit design 114. Synthesized circuit design 114 may specify circuit design 110 in terms of the primitives available on the particular IC in which the circuit design is to be implemented (e.g., the target IC).

In the example of FIG. 1, synthesis tool 102 has transformed HDL memory 112 into a memory circuit 116. In accordance with the inventive arrangements described herein, synthesis tool 102 is capable of automatically creating memory circuit 116 from a plurality of memory primitives available in the target IC. Memory circuit 116 further includes any read and/or write circuit(s), as automatically generated by synthesis tool 102, to support read and/or write operations via the ports of memory circuit 116. Memory circuit 116 may also include a latency compensation circuit described in greater detail hereinbelow.

Placement tool 104 is capable of performing placement to assign elements of synthesized circuit design 114 to particular instances of circuit blocks and/or resources having specific locations on the target IC. Routing tool 106 is capable of routing the placed circuit design. EDA tool(s) 108, if included, may perform additional operations. The additional operations may include, but are not limited to, performing certain optimizations and/or preparing the circuit design for implementation as hardware within an IC. For example, the additional operations may include generation of configuration data (e.g., a configuration bitstream) that may be loaded into the target IC.

System 100, subsequent to performing one or more or all of synthesis, placement, routing, and/or other operations, outputs processed circuit design 118. Processed circuit design 118 may be implemented in the target IC. That is, processed circuit design 118 may be physically realized in the target IC. In one aspect, the target IC is a programmable IC. An example of a programmable IC is a field programmable gate array (FPGA) that includes programmable circuitry or logic or an IC that includes both dedicated or hardwired circuitry and programmable circuitry or logic. In one aspect, processed circuit design 118 may be specified as configuration data that, upon loading into the target IC physically realizes circuit design 110, including memory circuit 116, therein.

System 100 is capable of automatically implementing any of a variety of HDL memories that may be specified in user circuit designs. In one aspect, system 100 utilizes a technique that is agnostic to the particular limitations of the memory primitives that are used. This allows system 100 to automatically implement HDL RAMs detected within user circuit designs for any of a variety of different target ICs that may utilize varying and/or different memory primitives. Thus, while the architecture of ICs and memory primitives for such ICs may change over time, system 100 is capable of continuing to automatically implement HDL RAMs within such ICs without modification.

Within this disclosure, for purposes of illustration and ease of description, the following terms are used and/or defined. The term “HDL memory” means a technology independent description of a particular memory of a circuit design to be implemented on a target IC. The HDL memory may be specified as a RAM type of memory.

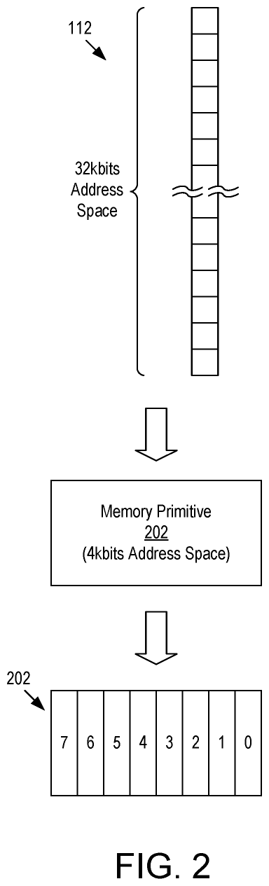

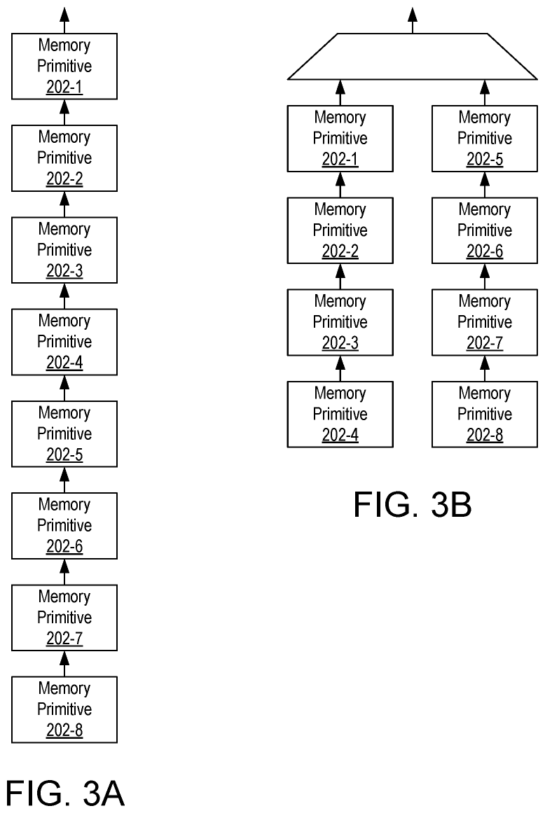

FIG. 2 is a visualization of HDL memory 112 from Example 1 and an example memory primitive 202 available within target IC in which circuit design 110 is to be implemented. As illustrated, HDL memory 112 is 32 k by 1 bit. That is, HDL memory 112 has a 32 k depth (32 k entries) and a width of 1 bit resulting in a 32 kbit address space. Memory primitive 202 has a 4 kbit address space. If HDL memory 112 were implemented using conventional EDA tools, a memory architecture as illustrated in FIG. 3A (cascaded) or 3B (multiplexed) would be created that utilizes 8 different memory primitives 202 where only 1 bit of data is stored in each addressable byte leaving 7 unused bits.

In accordance with the inventive arrangements described herein, a memory may be implemented using significantly fewer memory primitives than illustrated in FIG. 3A or 3B. As discussed in greater detail below, at least for this example, the memory may be implemented using 2 memory primitives 202. In doing so, the inventive arrangements implement read and write circuitry that uses what would otherwise be vacant or unused bits of the memory primitive by “folding” and re-using the address space. As shown towards the bottom of FIG. 2, memory primitive 202 may be partitioned into 8 sections (0-7). The data among each of the 8 partitions is stored inside the same memory using different bits. For example, the data may be folded such that a single addressable byte is subdivided into 8 partitions of 1 bit each so that the full capacity of the byte is utilized.

In accordance with the inventive arrangements, because memory primitive 202 must read and write a data item of a particular size, e.g., an entire byte of data in this example, read and write circuitry is synthesized to select the appropriate bits to be read out and to ensure that the appropriate bits are written.

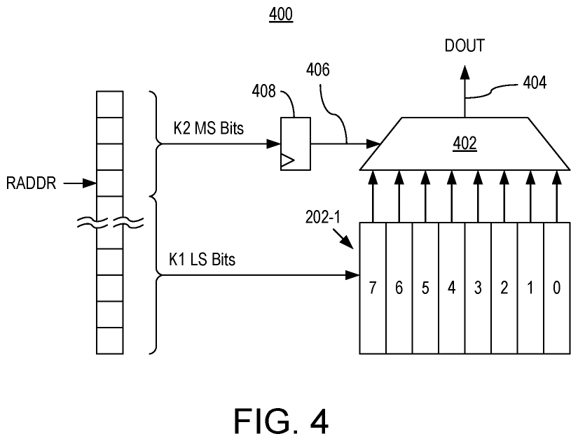

FIG. 4 illustrates an example of a read circuit 400 generated by system 100 of FIG. 1 for an HDL memory. For purposes of illustration, FIG. 4 is described with reference to HDL memory 112 of Example 1. It should be appreciated, however, that the principles described within this disclosure may be used to implement other HDL memories of different depths and/or widths using different types of memory primitives.

In the example of FIG. 4, a first instance of memory primitive 202, shown as 202-1, is used. As shown, memory primitive 202-1, also referred to herein as a “first memory primitive,” is coupled to a multiplexer 402. As discussed, memory primitive 202-1 is configured to read out one byte of data on each read. Because fewer than 8 bits of data are needed for each read, the particular bit or bits ultimately output from read circuit 400 as DOUT (e.g., read data) are selected by multiplexer 402. Multiplexer 402 selects the particular bit or bits output from memory primitive 202-1, which are output as signal 404. The particular bit or bits output from multiplexer 402 are selected based on, and responsive to, control signal 406.

In the example, a read address (RADDR) is provided to the memory to perform a read operation. RADDR has a width of K bits and is formed of two portions K1 and K2 where K=K1+K2 (e.g., as concatenated). K1 represents least significant bits of RADDR. K2 represents most significant bits of RADDR. In the example, K1 is provided to memory primitive 202-1 to select the particular data item (e.g., a byte in this example) that is read out and provided to multiplexer 402. Continuing with HDL memory 112 of Example 1, memory primitive 202-1 is subdivided into 8 partitions 0-7. The data item, i.e., byte, read out will include one bit from each of partitions 0-7. K2 is provided to a register 408. The output from register 408 is provided to multiplexer 402 as control signal 406, which selects one of the 8 bits to pass as signal 404.

Given that memory primitive 202-1 has 4 kbits of address space, K1 will be 12 bits. The value of K1 may be determined as log 2 (max_addr_space), where “max_addr_space” specifies the maximum address space available in the primitive. In this example, log 2 (4096)=12, with the address space of memory primitive being 2\hat{ }K1. The value of K2 may be determined as log 2 (m/n), where m specifies the minimum configurable width of the memory primitive and n specifies the width of the HDL memory. Continuing with HDL memory 112 of Example 1, the value of m is 8, being the minimum width available from memory primitive 202-1. The value of n is 1 given that HDL memory 112 has a width of a single bit.

Appreciably, in cases where the width of the memory is greater than 1 bit, then the number of bits read out from memory primitive 202-1 using multiplexer 402 will be greater (e.g., the number of bits of the width of the memory). In this example, with a minimum width of the memory primitive 202 being 8 bits, the inventive arrangements may be used for HDL memories having widths of 1, 2, or 4. For example, in the case where the width of the HDL memory is 2, signal 406 may include 2 bits to select a set of 2 of the bits to be output (e.g., bits (0,1), (2,3), (4,5), or (6,7)).

The inventive arrangements may be used with any of a variety of different memory primitives of differing sizes so long as the various metrics and implementation rules described within this disclosure are observed.

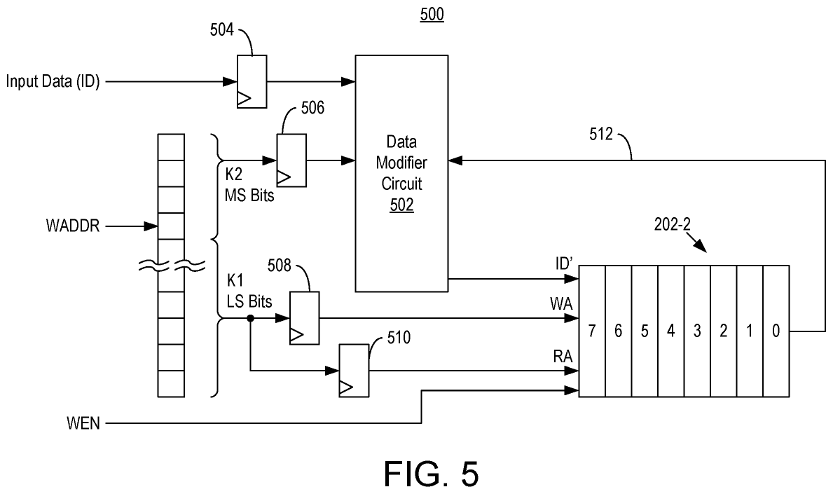

FIG. 5 illustrates an example of a write circuit 500 generated by system 100 of FIG. 1 for an HDL memory. For purposes of illustration, FIG. 5 is described with reference to HDL memory 112 of Example 1. It should be appreciated, however, that the principles described within this disclosure may be used to implement other HDL memories of different widths using different types of memory primitives.

In the example of FIG. 5, a second instance of memory primitive 202, shown as 202-2, is used. That is, the second instance of memory primitive 202 may be matched or identical to the first instance of memory primitive 202. Within this disclosure, memory primitive 202-2 is also referred to as a “second memory primitive.” As illustrated, memory primitive 202-2 is coupled to a modifier circuit 502. Input data (ID) is received into register 504, which is conveyed to modifier circuit 502. The ID is data to be written to memory. The input data has a width of DIN bits, which is the width of the HDL memory. The K2 most significant bits of the write address (WADDR) are provided to register 506 and also conveyed to modifier circuit 502. The K1 least significant bits of WADDR are conveyed to register 508 and to register 510. Register 508 conveys the K1 least significant bits to the write address (WA) port of memory primitive 202-2. Register 510 conveys the K1 least significant bits to the read address (RA) port of memory primitive 202-2. A write enable (WEN) signal is also provided to a write enable port of memory primitive 202-2.

Because memory primitive 202-2 does not support single bit writes (e.g., memory primitive 202-2 supports 1 byte reads and writes as previously described in connection with memory primitive 202-1), 8 bits must be written on each write operation. In consequence, memory locations, e.g., bits, that are not intended to be written for the HDL memory 112 still must be written when writing a single bit to memory primitive 202-2.

In the example, the particular byte that is to be written is specified by the K1 least significant bits and specified to memory primitive 202-2 as a read address (RA) to read out that byte. The byte is read out and provided to modifier circuit 502 via signal 512. The data conveyed by signal 512 may also be referred to herein as RAM data. Modifier circuit 502 receives the byte of data as read out from memory primitive 202-2. In addition, modifier circuit 502 receives the particular bit(s) of ID to be written to memory primitive 202-2 as well as the K2 most significant bits of WADDR that specify the position of the bit(s) within the byte just read from memory primitive 202-2 that must be updated with the ID. Modifier circuit 502 updates the particular bit(s) indicated by the K2 most significant bits with the bit(s) from the ID.

For purposes of illustration, consider an example in which the byte of data specified by the K1 least significant bits of data that is read from memory primitive 202-2 is 8′b [a,b,c,d,e,f,g,h]. The value of the ID may be “v” and is to be written at WADDR (K1 concatenated with K2). K2 is used by modifier circuit 502 to decode into the particular bit location(s) of the byte 8′b [a,b,c,d,e,f,g,h] to write the value “v” thereto. For example, if K2=“000”, modifier circuit 502 writes the value “v” to the 0 partition of the byte resulting in the byte 8′b [a,b,c,d,e,f,g,v]. If K2=“111”, modifier circuit 502 writes the value “v” to the 7 partition of the byte resulting in the byte 8′b [v,b,c,d,e,f,g,h].

The byte of data, as updated by modifier circuit 502, is represented by ID′ in FIG. 5. ID′ is a function of the ID, the K2 most significant bits of the write address (WADDR), and the RAM data conveyed by signal 512. ID′ is written back to the address specified by the K1 least significant bits of WADDR as provided to the write address (WA) port of memory primitive 202-2. The operations of modifier circuit 502 ensure that those bits of the byte requiring updating from memory primitive 202-2 are left unchanged and that only those bits, as specified by K2, are updated. The entire byte is written back to memory primitive 202-2.

The actual writing of the write data to memory primitive 202-2 occurs one clock cycle after the intended write, which is the arrival of the input data IN and WADDR. This is the case because the data item with which the read data must be combined is read out of memory primitive 202-2 on the clock cycle that WADDR and ID are received, combined with the write data by modifier circuit 502, and written back to the same location in memory primitive 202-2 from which the byte was originally read in the next clock cycle. This delay presents a challenge if ID is to be immediately read in the clock cycle following receipt of IN by write circuit 500 because that data has not yet been written. Latency mitigation circuitry is described below in greater detail to address this issue.

As illustrated in the example of FIG. 5, the write operation utilizes both a “read” port and a “write” port. For those cases where the memory primitive includes two ports, additional ports are required to implement read circuit 400. For this reason, the read circuit 400 and the write circuit 500 are implemented using separate memory primitives.

As discussed, though operation of memory primitive 202-2 is described in terms of reading and writing bytes of data, the particular unit of data that is the minimum amount that may be addressed may vary based on the particular memory primitive that is used. As such, reference to bytes as the data item is not intended as a limitation of the inventive arrangements described herein.

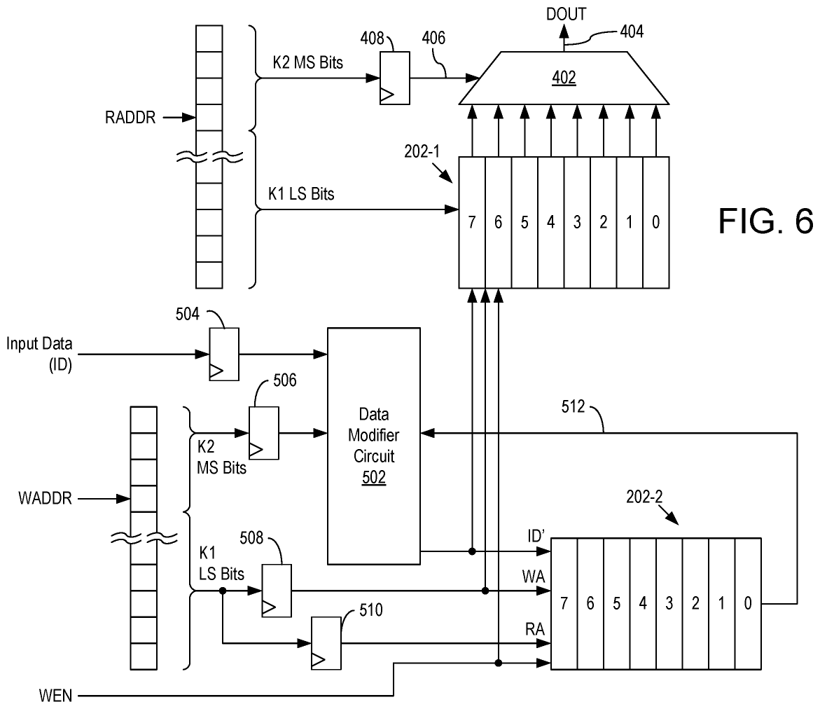

FIG. 6 illustrates a memory 600 formed of read circuit 400 and write circuit 500. In the example, the signals corresponding to ID′, WA, and RA of write circuit 500 are connected to a second port of first memory primitive 202-1 to synchronize any data being written to second memory primitive 202-2 to first memory primitive 202-1.

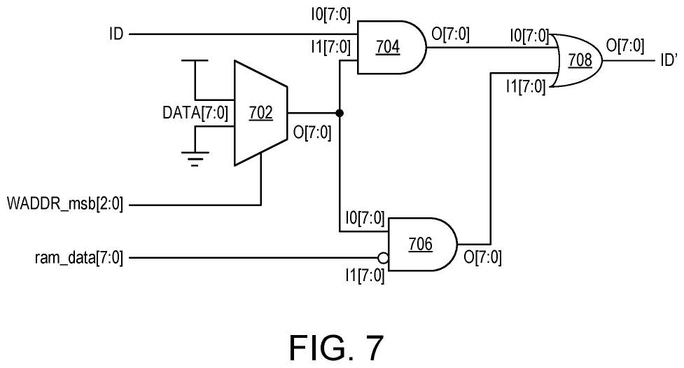

FIG. 7 illustrates an example of modifier circuit 502. The data written to memory 600, e.g., ID′, is created by merging data read from the write memory with the input data ID via a mask. In the example, modifier circuit 502 includes a multiplexer 702, an AND logic gate (AND gate) 704, an AND logic gate (AND gate) 706, and an OR logic gate (OR gate) 708. For purposes of illustration, modifier circuit 502 is configured to write 8 bits of data, e.g., a byte, back to second memory primitive 202-2 and the partition size is 1 bit.

Multiplexer 702 is configured to generate the mask. For purposes of illustration, consider an example in which the 3^{rd} bit of data is being written. In that case, the mask generated by multiplexer 702 will be 8′b00000100. Multiplexer 702 includes two 8-bit input ports with a first port being tied to a logic high (e.g., VDD) and the second port being tied to a logic low (e.g., GND). The 3 most significant bits of WADDR are provided to multiplexer 702 as a select signal indicating which bit to set high in the resulting mask.

AND gate 704 ensures that only the 3^{rd} bit, in this example, of the ID is propagated by masking. For purposes of illustration, IN=d, which may be expanded to 8′b{d,d,d,d,d,d,d,d}. When the expanded data is processed through AND gate 704 using the mask 8′b{0,0,0,0,0,1,0,0}, the data is filtered out with the exception of the 3^{rd} bit resulting in an output of 8′b{0,0,0,0,0,d,0,0,0}.

AND gate 706 ensures that all of the data read out of second memory primitive 202-2 as conveyed via signal 512 (RAM data), except for the 3^{rd} bit in this example, is propagated. This is achieved by invert-masking the data read from the memory. If the data read from the memory is 8′b{x,y,z,w,p,q,r,s}, due to the inverting input, AND gate 706 outputs 8′b{x,y,z,w,0,q,r,s}.

OR gate 708 combines the outputs of AND gate 704 and AND gate 706 to generate ID′, which is written back to second memory primitive 202-2 at the address indicated by the most significant bits of WADDR. In this example, OR gate 708 outputs an ID′ of 8′b{x,y,z,w,d,q,r,s} that caries the original ID of d in the 3^{rd} bit. As illustrated, the 3^{rd} bit of data now carries the ID while all of the other bits are same as the original memory content.

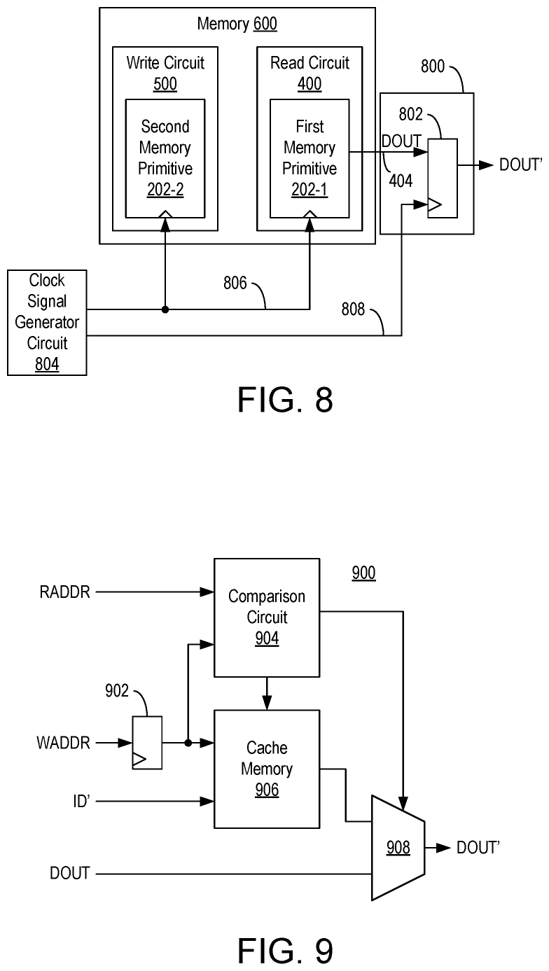

FIGS. 8 and 9 illustrate different examples of latency compensation circuitry. The latency compensation circuitry may be used to address the scenario in which a circuit is attempting to read data in the next clock cycle immediately following the clock cycle on which a write operation is initiated. Recall from the example of FIGS. 5 and 6 that there is a one cycle delay in placing updated data from a write operation into memory primitive 202-1. Accordingly, without latency compensation circuitry, were a circuit to read data in the clock cycle immediately following the initiation of a write operation, old or stale data would be read and output.

FIG. 8 illustrates an example latency compensation circuit 800. Latency compensation circuit 800 register 802. Register 802 may be used to re-clock signal 404 as output from memory primitive 202-1. Register 802 may be clocked at one-half of the frequency or clock rate used to clock write circuit 500 and read circuit 400. In the example, clock signal generator circuit (CSGC) 804 generates two clock signals 806 and 808. Clock signal 806 has twice the frequency of clock signal 808 (or clock signal 808 has one-half the frequency of clock signal 806). By including register 802 as latency compensation circuit 800, any circuits receiving read data output from memory 600 will receive accurate read data. That is, any time that a circuit attempts to read data on a clock cycle immediately following the writing of data will receive the correct data as opposed to stale data. The synchronized read data is depicted as DOUT′.

FIG. 9 illustrates another example latency compensation circuit 900. In the example of FIG. 9, a latency compensation circuit 900 includes a register 902 which delays WADDR by one clock cycle, a comparison circuit 904, a cache memory 906, and a multiplexer 908. As illustrated, cache memory 906 is configured to store a prior WADDR (e.g., from the clock cycle prior) along with the write data (e.g., the data specified by ID′ being written back to second memory primitive 202-2). Comparison circuit 904 is configured to compare a current read address (e.g., RADDR) with the prior write address (the prior WADDR). In response to comparison circuit 904 detecting a match between the current RADDR and the prior WADDR, comparison circuit 904 signals cache memory 906 to output the cached (e.g., stored) value of ID′. Also, in response to detecting a match, comparison circuit 904 signals multiplexer 908 to output or pass the value obtained from cache memory 906. Otherwise, comparison circuit 904 signals multiplexer 908 to pass the value conveyed by signal 404 as DOUT (e.g., the output from multiplexer 402 of read circuit 400). The synchronized read data is depicted as DOUT′.

Example 2 below illustrates sample HDL specifying the latency compensation circuit 900 of FIG. 9.

### Example 2

```
// Cache the incoming data
reg [DW-1:0] cache_data;
reg [AW-1:0] prev_waddr;
always @(posdge clk) begin
  if (wen) begin
    cached_data <= din
    prev_waddr <= waddr;
  end
end
always @(posedge clk) begin
  ramout <= mem[addr];
end;
always @ (*) begin
  if (raddr == prev_waddr)
    dout <= cached_data
  else
    dout <= memory_read_data
```

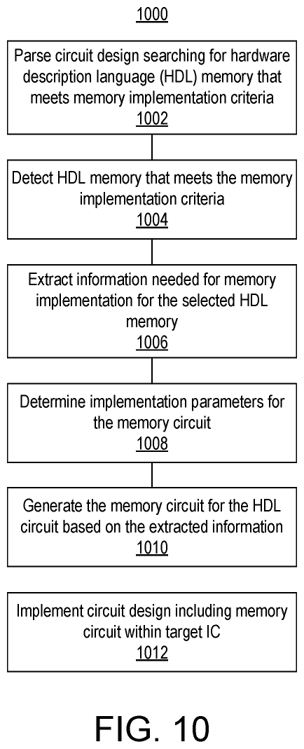

FIG. 10 is an example method 1000 of implementing a memory as described within this disclosure. Method 1000 may be performed by a data processing system executing suitable program code such as the example architecture of FIG. 1. An example of a data processing system is described herein in connection with FIG. 13.

In block 1002, synthesis tool 102 is capable of parsing circuit design 110 searching for an HDL memory that meets the memory implementation criteria. The memory implementation criteria include an HDL memory specified in circuit design 110 that has disjoint read and write addresses (e.g., separate or independent read and write addresses) and has a width that is narrower than a narrowest available configuration of the memory primitive on the target IC. In one or more example implementations, the width of the HDL memory should be less than or equal to ½ the minimum or narrowest possible width of the memory primitive that will be used to implement the memory circuit.

For example, synthesis tool 102 is capable of evaluating the width n of the HDL memory and the minimum configurable width m of the memory primitive(s) to be used to implement the memory circuit. Synthesis tool 102 determines whether n≤(m/2) to ensure that the width is less than or equal to ½ the minimum configurable width of the memory primitive(s) to be used. In addition, synthesis tool 102 is capable ensuring that m and n are both powers of 2. Synthesis tool 102 is capable evaluating each of the HDL memories found within circuit design 110 and performing the checks and comparisons described.

In cases where n=(m/2), the number of memory primitives used to implement the memory circuit may not be less than the number of memory primitives used with other available memory implementation techniques. In cases where n<(m/2), the number of memory primitives used to implement the memory circuit will be less than the number of memory primitive used with other available memory implementation techniques.

In block 1004, synthesis tool 102 detects an HDL memory within circuit design 110 that meets the memory implementation criteria. Synthesis tool 102 selects the HDL memory. It should be appreciated that while method 1000 is described with reference to processing one HDL memory, a set of HDL memories meeting the memory implementation criteria may be selected and processed through the process described within this disclosure.

In block 1006, synthesis tool 102 is capable of extracting information needed for memory implementation for the selected HDL memory from circuit design 110. For example, synthesis tool 102 is capable of extracting the width n of the HDL memory, the depth D of the HDL memory, the minimum configurable width m of the memory primitive(s) to be used to implement the memory circuit, the depth d of the memory primitive(s) to be used to implement the memory circuit.

In block 1008, synthesis tool 102 is capable of determining implementation parameters of the memory circuit. For example, synthesis tool 102 is capable of determining the max_addr_space as D×m using the extracted parameters. The value of K1 may be determined as log 2 (max_addr_space). The value of K2 may be determined as log 2 (m/n). As discussed, K=K1+K2 (e.g., in terms of total bit width). Further, K, which specifies the total address width of the memory circuit being implemented, meets the following condition: 2^{(K-1)}<D≤2^{K}. As an example, 2\hat{ }14<20000<2\hat{ }15 where K=15 in this example. Further, synthesis tool 102 is capable of determining that the memory circuit will include 2^{K2} partitions.

In block 1010, synthesis tool 102 is capable of generating memory circuit 116. Synthesis tool 102 generates HDL specifying a read circuit, a write circuit, and a latency compensation circuit for the memory circuit. Synthesis tool 102 may also generate the necessary configuration data to configure the memory circuit, including the first memory primitive used and the second memory primitive used, to operate with the necessary width.

In block 1012, system 100 implements the circuit design within the target IC. For example, system 100 may complete the design flow by performing place and route and/or any other optimizations. System 100 may generate configuration data (e.g., a configuration bitstream) specifying a physical realization of circuit design 110. The configuration data may be loaded into the target IC to physically realize circuit design 110 therein, including the memory circuit having an architecture the same as or similar to that described within this disclosure.

In one or more example implementations, the particular latency compensation circuit that is implemented may depend on the particular operating frequencies of the memory circuit and the other circuits that access data therefrom. For example, if the clock frequency ratios are supported by the target IC to implement latency compensation circuit 800, system 100 may select that circuit over latency compensation circuit 900. Alternatively, the user may specify through a preference which latency compensation circuit to implement.

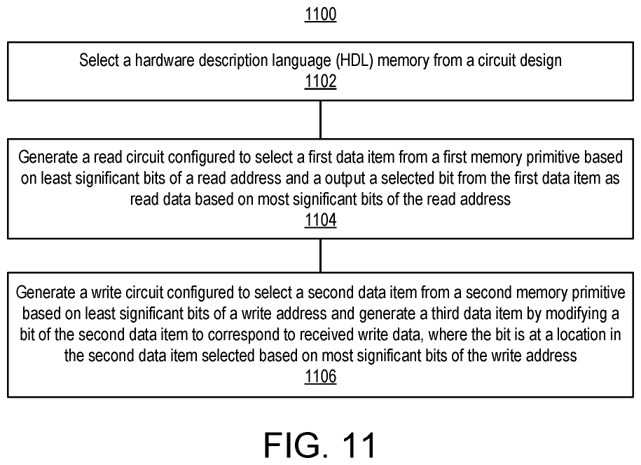

FIG. 11 is another example method 1100 of implementing a memory as described within this disclosure. Method 1100 may be performed by a data processing system executing suitable program code such as shown in the example architecture of FIG. 1. An example of a data processing system is described herein in connection with FIG. 13. The operations of FIG. 11 may be performed by system 100 of FIG. 1.

In block 1102, the system is capable of selecting an HDL memory from circuit design 110. In block 1104, the system is capable of generating a read circuit. The read circuit is configured to select a first data item from a first memory primitive based on least significant bits of a read address (RADDR) and output a selected bit (e.g., DOUT) from the first data item as read data based on most significant bits of the read address. In block 1106, the system is capable of generating a write circuit. The write circuit is configured to select a second data item (e.g., data conveyed on signal 512) from a second memory primitive based on least significant bits of a write address (WADDR) and generate a third data item (ID′ for purposes of FIG. 11) by modifying a bit of the second data item to correspond to received write data (ID) at a location selected based on most significant bits of the write address. The write circuit further is configured to write the third data item to a location in the second memory primitive based on the least significant bits of the write address.

The foregoing and other implementations can each optionally include one or more of the following features, alone or in combination. Some example implementations include all the following features in combination.

In one or more aspects, the first memory primitive and the second memory primitive may be same types of memory primitives.

In one or more aspects, the HDL memory has disjoint read and write addresses and has a narrower width than a memory primitive used to implement the HDL memory for a target integrated circuit.

In one or more aspects, the third data item is written to a location in the first memory primitive based on the least significant bits of the write address.

In one or more aspects, the selected bit from the first data item and the bit of the second data item that is modified each comprise a plurality of bits.

In one or more aspects, a number of the plurality of bits is less than one-half of a minimum width of the memory primitives. For example, the first memory primitive and the second memory primitive have a same minimum width and a number of the plurality of bits is less than one-half of the minimum width of the first memory primitive.

In one or more aspects, each of the first memory primitive and the second memory primitive is partitioned into a plurality of partitions based on a number of the most significant bits of the read address.

In one or more aspects, the first memory primitive and the second memory primitive have a same minimum width denoted as m, a width of the memory is denoted as n, each of m and n is a power of two, and n<(m/2).

In one or more aspects, the method includes generating a write latency mitigation circuit configured to store a most recent one of the write data and a prior write address in a cache memory, compare the read address with the prior write address, and, in response to the read address matching the prior write address, outputting the write data stored in the cache memory as the read data for a read operation.

In one or more aspects, the method includes generating a write latency mitigation circuit including an output register coupled to the read circuit, wherein the output register is clocked at one-half of a clock rate of the write circuit and the read circuit.

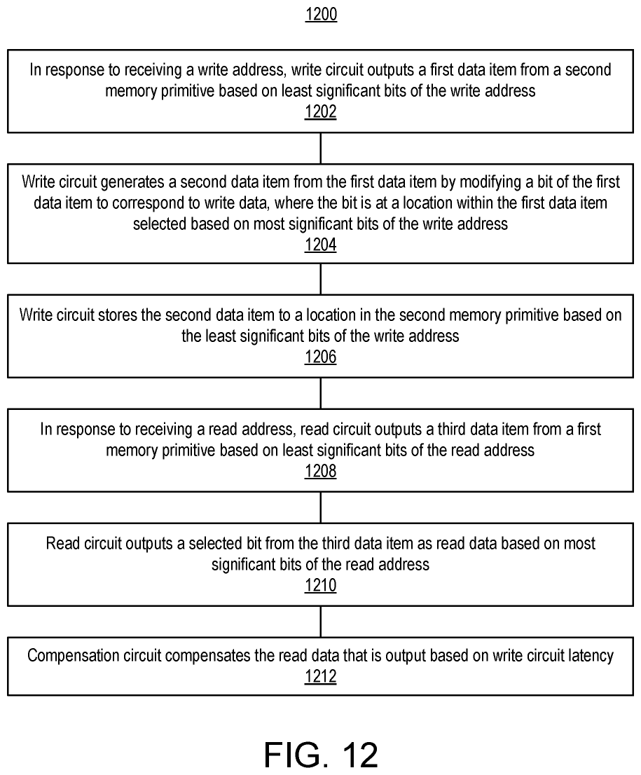

FIG. 12 is an example method 1200 of operation of a memory circuit generated as described within this disclosure. In block 1202, in response to receiving a write address, the write circuit outputs a first data item (e.g., data conveyed on signal 512) from a second memory primitive based on least significant bits of the write address (WADDR). In block 1204, the write circuit generates a second data item (ID′ for purposes of FIG. 12) from the first data item by modifying a bit of the first data item to correspond to write data at a location within the first data item selected based on most significant bits of the write address. In block 1206, the write circuit stores the second data item to a location in the second memory primitive based on the least significant bits of the write address.

In block 1208, in response to receiving a read address (RADDR), the read circuit outputs a third data item (DOUT) from a first memory primitive based on least significant bits of the read address. In block 1210, the read circuit outputs a selected bit from the third data item as read data based on most significant bits of the read address. In block 1212, the compensation circuit compensates read data that is output for read operations based on write latency (e.g., DOUT′).

FIG. 13 illustrates an example implementation of a data processing system 1300. As defined herein, the term “data processing system” means one or more hardware systems configured to process data, each hardware system including at least one processor and memory, wherein the processor is programmed with computer-readable instructions that, upon execution, initiate operations. Data processing system 1300 can include a processor 1302, a memory 1304, and a bus 1306 that couples various system components including memory 1304 to processor 1302.

Processor 1302 may be implemented as one or more processors. In an example, processor 1302 is implemented as a central processing unit (CPU). Processor 1302 may be implemented as one or more circuits, e.g., a hardware processor or hardware processors, capable of carrying out instructions contained in program code. The circuit may be an integrated circuit or embedded in an integrated circuit. Processor 1302 may be implemented using a complex instruction set computer architecture (CISC), a reduced instruction set computer architecture (RISC), a vector processing architecture, or other known architectures. Example processors include, but are not limited to, processors having an x86 type of architecture (IA-32, IA-64, etc.), Power Architecture, ARM processors, and the like.

Bus 1306 represents one or more of any of a variety of communication bus structures. By way of example, and not limitation, bus 1306 may be implemented as a Peripheral Component Interconnect Express (PCIe) bus. Data processing system 1300 typically includes a variety of computer system readable media. Such media may include computer-readable volatile and non-volatile media and computer-readable removable and non-removable media.

Memory 1304 can include computer-readable media in the form of volatile memory, such as random-access memory (RAM) 1308 and/or cache memory 1310. Data processing system 1300 also can include other removable/non-removable, volatile/non-volatile computer storage media. By way of example, storage system 1312 can be provided for reading from and writing to a non-removable, non-volatile magnetic and/or solid-state media (not shown and typically called a “hard drive”), which may be included in storage system 1312. Although not shown, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM or other optical media can be provided. In such instances, each can be connected to bus 1306 by one or more data media interfaces. Memory 1304 is an example of at least one computer program product.

Memory 1304 is capable of storing computer-readable program instructions that are executable by processor 1302. For example, the computer-readable program instructions can include an operating system, one or more application programs, other program code, and program data. For example, memory 1304 may store an executable architecture having one or more tools as illustrated in FIG. 1 and included in system 100.

Processor 1302, in executing the computer-readable program instructions, is capable of performing the various operations described herein that are attributable to a computer. It should be appreciated that data items used, generated, and/or operated upon by data processing system 1300 are functional data structures that impart functionality when employed by data processing system 1300. As defined within this disclosure, the term “data structure” means a physical implementation of a data model's organization of data within a physical memory. As such, a data structure is formed of specific electrical or magnetic structural elements in a memory. A data structure imposes physical organization on the data stored in the memory as used by an application program executed using a processor.

Data processing system 1300 may include one or more Input/Output (I/O) interfaces 1318 communicatively linked to bus 1306. I/O interface(s) 1318 allow data processing system 1300 to communicate with one or more external devices and/or communicate over one or more networks such as a local area network (LAN), a wide area network (WAN), and/or a public network (e.g., the Internet). Examples of I/O interfaces 1318 may include, but are not limited to, network cards, modems, network adapters, hardware controllers, etc. Examples of external devices also may include devices that allow a user to interact with data processing system 1300 (e.g., a display, a keyboard, and/or a pointing device) and/or other devices such as accelerator card.

Data processing system 1300 is only one example implementation. Data processing system 1300 can be practiced as a standalone device (e.g., as a user computing device or a server, as a bare metal server), in a cluster (e.g., two or more interconnected computers), or in a distributed cloud computing environment (e.g., as a cloud computing node) where tasks are performed by remote processing devices that are linked through a communications network. In a distributed cloud computing environment, program modules may be located in both local and remote computer system storage media including memory storage devices.

The example of FIG. 13 is not intended to suggest any limitation as to the scope of use or functionality of example implementations described herein. Data processing system 1300 is an example of computer hardware that is capable of performing the various operations described within this disclosure. In this regard, data processing system 1300 may include fewer components than shown or additional components not illustrated in FIG. 13 depending upon the particular type of device and/or system that is implemented. The particular operating system and/or application(s) included may vary according to device and/or system type as may the types of I/O devices included. Further, one or more of the illustrative components may be incorporated into, or otherwise form a portion of, another component. For example, a processor may include at least some memory.

The terminology used herein is for the purpose of describing particular embodiments only and is not intended to be limiting. Notwithstanding, several definitions that apply throughout this document are expressly defined as follows.

As defined herein, the singular forms “a,” “an,” and “the” are intended to include the plural forms as well, unless the context clearly indicates otherwise.

As defined herein, the terms “at least one,” “one or more,” and “and/or,” are open-ended expressions that are both conjunctive and disjunctive in operation unless explicitly stated otherwise. For example, each of the expressions “at least one of A, B, and C,” “at least one of A, B, or C,” “one or more of A, B, and C,” “one or more of A, B, or C,” and “A, B, and/or C” means A alone, B alone, C alone, A and B together, A and C together, B and C together, or A, B and C together.

As defined herein, the term “automatically” means without human intervention.

As defined herein, the term “computer-readable storage medium” means a storage medium that contains or stores program instructions for use by or in connection with an instruction execution system, apparatus, or device. As defined herein, a “computer-readable storage medium” is not a transitory, propagating signal per se. The various forms of memory, as described herein, are examples of computer-readable storage media. A non-exhaustive list of examples of computer-readable storage media include an electronic storage device, a magnetic storage device, an optical storage device, an electromagnetic storage device, a semiconductor storage device, or any suitable combination of the foregoing. A non-exhaustive list of more specific examples of a computer-readable storage medium may include: a portable computer diskette, a hard disk, a RAM, a read-only memory (ROM), an erasable programmable read-only memory (EPROM or Flash memory), an electronically erasable programmable read-only memory (EEPROM), a static random-access memory (SRAM), a portable compact disc read-only memory (CD-ROM), a digital versatile disk (DVD), a memory stick, a floppy disk, or the like.

As defined herein, the term “if” means “when” or “upon” or “in response to” or “responsive to,” depending upon the context. Thus, the phrase “if it is determined” or “if [a stated condition or event] is detected” may be construed to mean “upon determining” or “in response to determining” or “upon detecting [the stated condition or event]” or “in response to detecting [the stated condition or event]” or “responsive to detecting [the stated condition or event]” depending on the context.

As defined herein, the term “responsive to” and similar language as described above, e.g., “if,” “when,” or “upon,” means responding or reacting readily to an action or event. The response or reaction is performed automatically. Thus, if a second action is performed “responsive to” a first action, there is a causal relationship between an occurrence of the first action and an occurrence of the second action. The term “responsive to” indicates the causal relationship.

As defined herein, the term “user” refers to a human being.

As defined herein, the term “hardware processor” means at least one hardware circuit. The hardware circuit may be configured to carry out instructions contained in program code. The hardware circuit may be an integrated circuit. Examples of a hardware processor include, but are not limited to, a central processing unit (CPU), an array processor, a vector processor, a digital signal processor (DSP), a field-programmable gate array (FPGA), a programmable logic array (PLA), an application specific integrated circuit (ASIC), programmable logic circuitry, and a controller.

As defined herein, the terms “one embodiment,” “an embodiment,” “in one or more embodiments,” “in particular embodiments,” or similar language mean that a particular feature, structure, or characteristic described in connection with the embodiment is included in at least one embodiment described within this disclosure. Thus, appearances of the aforementioned phrases and/or similar language throughout this disclosure may, but do not necessarily, all refer to the same embodiment.

As defined herein, the term “output” means storing in physical memory elements, e.g., devices, writing to display or other peripheral output device, sending or transmitting to another system, exporting, or the like.

As defined herein, the term “substantially” means that the recited characteristic, parameter, or value need not be achieved exactly, but that deviations or variations, including for example, tolerances, measurement error, measurement accuracy limitations, and other factors known to those of skill in the art, may occur in amounts that do not preclude the effect the characteristic was intended to provide.

The terms first, second, etc. may be used herein to describe various elements. These elements should not be limited by these terms, as these terms are only used to distinguish one element from another unless stated otherwise or the context clearly indicates otherwise.

A computer program product may include a computer-readable storage medium (or media) having computer-readable program instructions thereon for causing a processor to carry out aspects of the inventive arrangements described herein. Within this disclosure, the term “program code” is used interchangeably with the term “program instructions.” Computer-readable program instructions described herein may be downloaded to respective computing/processing devices from a computer-readable storage medium or to an external computer or external storage device via a network, for example, the Internet, a LAN, a WAN and/or a wireless network. The network may include copper transmission cables, optical transmission fibers, wireless transmission, routers, firewalls, switches, gateway computers and/or edge devices including edge servers. A network adapter card or network interface in each computing/processing device receives computer-readable program instructions from the network and forwards the computer-readable program instructions for storage in a computer-readable storage medium within the respective computing/processing device.

Computer-readable program instructions for carrying out operations for the inventive arrangements described herein may be assembler instructions, instruction-set-architecture (ISA) instructions, machine instructions, machine dependent instructions, microcode, firmware instructions, or either source code or object code written in any combination of one or more programming languages, including an object-oriented programming language and/or procedural programming languages. Computer-readable program instructions may include state-setting data. The computer-readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a LAN or a WAN, or the connection may be made to an external computer (for example, through the Internet using an Internet Service Provider). In some cases, electronic circuitry including, for example, programmable logic circuitry, an FPGA, or a PLA may execute the computer-readable program instructions by utilizing state information of the computer-readable program instructions to personalize the electronic circuitry, in order to perform aspects of the inventive arrangements described herein.

Certain aspects of the inventive arrangements are described herein with reference to flowchart illustrations and/or block diagrams of methods, apparatus (systems), and computer program products. It will be understood that each block of the flowchart illustrations and/or block diagrams, and combinations of blocks in the flowchart illustrations and/or block diagrams, may be implemented by computer-readable program instructions, e.g., program code.

These computer-readable program instructions may be provided to a processor of a computer, special-purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer-readable program instructions may also be stored in a computer-readable storage medium that can direct a computer, a programmable data processing apparatus, and/or other devices to function in a particular manner, such that the computer-readable storage medium having instructions stored therein comprises an article of manufacture including instructions which implement aspects of the operations specified in the flowchart and/or block diagram block or blocks.

The computer-readable program instructions may also be loaded onto a computer, other programmable data processing apparatus, or other device to cause a series of operations to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various aspects of the inventive arrangements. In this regard, each block in the flowchart or block diagrams may represent a module, segment, or portion of instructions, which comprises one or more executable instructions for implementing the specified operations.

In some alternative implementations, the operations noted in the blocks may occur out of the order noted in the figures. For example, two blocks shown in succession may be executed substantially concurrently, or the blocks may sometimes be executed in the reverse order, depending upon the functionality involved. In other examples, blocks may be performed generally in increasing numeric order while in still other examples, one or more blocks may be performed in varying order with the results being stored and utilized in subsequent or other blocks that do not immediately follow. It will also be noted that each block of the block diagrams and/or flowchart illustration, and combinations of blocks in the block diagrams and/or flowchart illustration, may be implemented by special purpose hardware-based systems that perform the specified functions or acts or carry out combinations of special purpose hardware and computer instructions.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A memory, comprising:
a read circuit including:
a first memory primitive configured to output a first data item based on least significant bits of a read address;
a multiplexer coupled to the first memory primitive, the multiplexer configured to output a selected bit from the first data item as read data based on most significant bits of the read address; and
a write circuit coupled to the read circuit, the write circuit including:
a second memory primitive configured to output a second data item based on least significant bits of a write address; and
a modifier circuit configured to generate a third data item by modifying a bit of the second data item to correspond to write data, wherein the bit is at a location within the second data item selected based on most significant bits of the write address;
wherein the modifier circuit is configured to write the third data item to a location in the second memory primitive based on the least significant bits of the write address.

2. The memory of claim 1, wherein the third data item is written to a location in the first memory primitive based on the least significant bits of the write address.

3. The memory of claim 1, wherein the selected bit from the first data item and the bit of the second data item that is modified each comprise a plurality of bits.

4. The memory of claim 3, wherein the first memory primitive and the second memory primitive have a same minimum width and wherein a number of the plurality of bits is less than one-half of the minimum width of the first memory primitive.

5. The memory of claim 1, wherein each of the first memory primitive and the second memory primitive is partitioned into a plurality of partitions based on a number of the most significant bits of the read address.

6. The memory of claim 1, wherein the first memory primitive and the second memory primitive have a same minimum width denoted as m, a width of the memory is denoted as n, each of m and n is a power of two, and n<(m/2).

7. The memory of claim 1, further comprising:
a latency compensation circuit including:
a cache memory configured to store a most recent one of the write data and a prior write address; and
a comparison circuit configured to compare the read address with the prior write address;
wherein in response to the read address matching the prior write address, the write data stored in the cache memory is output as the read data for a read operation.

8. The memory of claim 1, further comprising:
a latency compensation circuit including an output register coupled to the read circuit, wherein the output register is clocked at one-half of a clock rate of the write circuit and the read circuit.

9. A method, comprising:
selecting a hardware description language (HDL) memory from a circuit design;
generating a read circuit configured to select a first data item from a first memory primitive based on least significant bits of a read address and output a selected bit from the first data item as read data based on most significant bits of the read address; and
generating a write circuit configured to select a second data item from a second memory primitive based on least significant bits of a write address and generate a third data item by modifying a bit of the second data item to correspond to write data, wherein the bit is at a location within the second data item selected based on most significant bits of the write address;
wherein the write circuit is configured to write the third data item to a location in the second memory primitive based on the least significant bits of the write address.

10. The method of claim 9, wherein the HDL memory has disjoint read and write addresses and has a narrower width than a memory primitive used to implement the HDL memory for a target integrated circuit.

11. The method of claim 9, wherein the third data item is written to a location in the first memory primitive based on the least significant bits of the write address.

12. The method of claim 9, wherein the selected bit from the first data item and the bit of the second data item that is modified each comprise a plurality of bits.

13. The method of claim 12, wherein the first memory primitive and the second memory primitive have a same minimum width and wherein a number of the plurality of bits is less than one-half of the minimum width of the first memory primitive.

14. The method of claim 9 wherein each of the first memory primitive and the second memory primitive is partitioned into a plurality of partitions based on a number of the most significant bits of the read address.

15. The method of claim 9, wherein the first memory primitive and the second memory primitive have a same minimum width denoted as m, a width of the memory is denoted as n, each of m and n is a power of two, and n<(m/2).

16. The method of claim 9, further comprising:
generating a latency compensation circuit configured to store a most recent one of the write data and a prior write address in a cache memory, compare the read address with the prior write address, and, in response to the read address matching the prior write address, outputting the write data stored in the cache memory as the read data for a read operation.

17. The method of claim 9, further comprising:
generating a latency compensation circuit including an output register coupled to the read circuit, wherein the output register is clocked at one-half of a clock rate of the write circuit and the read circuit.

18. A method, comprising:
in response to receiving a write address,
outputting a first data item from a second memory primitive based on least significant bits of the write address;
generating a second data item from the first data item by modifying a bit of the first data item to correspond to write data, wherein the bit is at a location within the first data item selected based on most significant bits of the write address; and
storing the second data item to a location in the second memory primitive based on the least significant bits of the write address.

19. The method of claim 18, further comprising:
in response to receiving a read address,
outputting a third data item from a first memory primitive based on least significant bits of the read address; and
outputting a selected bit from the third data item as read data based on most significant bits of the read address.

20. The method of claim 19, further comprising:
compensating the read data as output based on write circuit latency.
